(19) United States
(12) Patent Application Publication
(10) Pub. No.: US 2023/0120903 A1
(43) Pub. Date: Apr. 20, 2023

(54) Ultra High Surface Area Integrated Capacitor

(71) Applicant: 3D Glass Solutions, Inc., Albuquerque, NM (US)

(72) Inventors: Jeb H. Flemming, Albuquerque, NM (US); Jeff A. Bullington, Orlando, FL (US)

(21) Appl. No.: 17/910,590

(22) PCT Filed: Mar. 8, 2021
(86) PCT No.: PCT/US2021/021371

§ 371 Date: Sep. 9, 2022

Related U.S. Application Data
(60) Provisional application No. 62/988,158, filed on Mar. 11, 2020.

(51) Int. Cl. H01G 4/33; H01G 4/012

(52) U.S. Cl. CPC H01G 4/33; H01G 4/012; H01G 4/008

(57) ABSTRACT

The present invention includes a method of fabricating an integrated RF power condition capacitor with a capacitance greater than or equal to 1 nf and less than 1 mm², and a device made by the method.

### CROSS-REFERENCE AND REFERENCE TO RELATED APPLICATIONS

This PCT International Patent application claims priority to U.S. Provisional Patent Application Ser. No. 62/988,158 filed Mar. 11, 2020, the contents of which is incorporated by reference herein in its entirety.

### TECHNICAL FIELD OF THE INVENTION

The present invention relates to creating an integrated RF power conditioning capacitor.

### BACKGROUND OF THE INVENTION

Without limiting the scope of the invention, its background is described in connection with power condition capacitors.

RF devices are using higher and higher power. This class of RF devices produce pulses at voltages greater that 10 V and at currents greater than 2 Amps. Switching the signal on and off at this level of current and voltage creates a significant amount of harmonic signals. These harmonic signals can disrupt the operation of the circuit. Large value integrated silicon based capacitors fail to achieve the required capacitance and suffer from dielectric breakdown.

### SUMMARY OF THE INVENTION

The present inventors have developed integrated photodefinable glass-ceramics that can be converted from a glass phase to a ceramic phase through a combination of ultraviolet light exposure and thermal treatments. The selective application of the ultraviolet light exposure using a photo mask or shadow mask creates regions of ceramic material in the photodefinable glass. The present invention includes a method to fabricate a substrate with one or more, two or three-dimensional capacitive devices by preparing a photosensitive glass substrate with high surface area structures, dielectric material and coating with one or more metals.

In one embodiment of the present invention, a method of making an integrated large capacitance in a small form factor for power conditioning on a photodefinable glass includes: depositing a conductive seed layer on a photodefinable glass processed to form one or more via openings in the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; coating, at least once, at least a portion of the metal posts, the non-oxidizing layer, or both, with one or more nanoforms by electroplating to increase a surface area of the metal posts; depositing a dielectric layer on or around the posts; metal coating the dielectric layer to form a second electrode; connecting a first metal layer to all of the first electrodes in parallel to form a single electrode for a capacitor; and connecting a second metal layer to all of the second electrodes in parallel to form a second electrode for the capacitor. In one aspect, the dielectric layer is a thin film between 0.5 nm and 1000 nm thick. In another aspect, the dielectric layer is a sintered paste between 0.05 μm and 100 μm thick. In another aspect, the dielectric layer has an electrical permittivity between 10 and 10,000. In another aspect, the dielectric layer has an electrical permittivity between 2 and 100. In another aspect, the dielectric layer is deposited by ALD. In another aspect, the dielectric layer is deposited by doctor blading. In another aspect, the capacitor has a capacitance density greater than 1,000 pf/mm².

In another embodiment of the present invention, a method of making an integrated large capacitance in a small form factor for power conditioning on a photodefinable glass substrate includes: masking a circular pattern on the photosensitive glass substrate; exposing at least one portion of the photosensitive glass substrate to an activating UV energy source; heating the photosensitive glass substrate to a heating phase of at least ten minutes above its glass transition temperature; cooling the photosensitive glass substrate to transform at least part of the exposed glass to a crystalline material to form a glass—ceramic crystalline substrate; partially etching away the ceramic phase of the photodefinable glass substrate with an etchant solution; depositing a conductive seed layer on the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; depositing a dielectric layer on or around the posts; coating, at least once, at least a portion of the metal posts, the non-oxidizing layer, or both, with one or more nanoforms by electroplating to increase a surface area of the metal posts; metal coating the dielectric layer to form a second electrode; connecting a first metal layer to all of the first electrodes in parallel to form a single electrode for a capacitor; and connecting a second metal layer to all of the second electrodes in parallel to form a second electrode for a capacitor. In one aspect, the dielectric layer is a thin film between 0.5 nm and 1000 nm thick. In another aspect, the dielectric layer is a sintered paste between 0.05 μm and 100 μm thick. In another aspect, the dielectric layer has an electrical permittivity between 10 and 10,000. In another aspect, the dielectric layer has an electrical permittivity between 2 and 100. In another aspect, the dielectric layer is deposited by ALD. In another aspect, the dielectric layer is deposited by doctor blading. In another aspect, the capacitor has a capacitance density greater than 1,000 pf/mm².

Yet another embodiment of the present invention includes an integrated capacitor made by a method including: masking a circular pattern on a photosensitive glass substrate; exposing at least one portion of the photosensitive glass substrate to an activating UV energy source; heating the photosensitive glass substrate to a heating phase of at least ten minutes above its glass transition temperature; cooling the photosensitive glass substrate to transform at least part of the exposed glass to a crystalline material to form a glass—ceramic crystalline substrate; partially etching away the ceramic phase of the photodefinable glass substrate with an etchant solution; depositing a conductive seed layer on the photodefinable glass; placing the photodefinable glass substrate with a metallized seed layer electroplating metal to fill one or more openings in the photodefinable glass substrate to form vias; chemically-mechanically polishing a front and a back surface of the photodefinable glass substrate to leave only the filled vias; exposing and converting at least one rectangular portion of the photosensitive glass substrate around two adjacent filled vias; etching the rectangular patent exposing at least one pair of adjacent filled vias to form metal posts; flash coating a non-oxidizing layer on the metal posts that form a first electrode; depositing a dielectric layer on or around the posts; coating, at least once, at least a portion of the metal posts, the non-oxidizing layer, or both, with one or more nanoforms by electroplating to increase a surface area of the metal posts; metal coating the dielectric layer to form a second electrode; connecting a first metal layer to all of the first electrodes in parallel to form a single electrode for a capacitor; and connecting a second metal layer to all of the second electrodes in parallel to form a second electrode for the capacitor. In one aspect, the dielectric layer is a thin film between 0.5 nm and 1000 nm thick. In another aspect, the dielectric layer is a sintered paste between 0.05 μm and 100 μm thick. In another aspect, the dielectric material has an electrical permittivity between 10 and 10,000. In another aspect, the dielectric thin film has an electrical permittivity between 2 and 100. In another aspect, the dielectric thin film material is deposited by ALD. In another aspect, the dielectric paste material is deposited by doctor blading. In another aspect, the capacitor has a capacitance density greater than 1,000 pf/mm².

### BRIEF DESCRIPTION OF THE DRAWINGS

For a more complete understanding of the features and advantages of the present invention, reference is now made to the detailed description of the invention along with the accompanying figures and in which:

FIG. 1 shows the image of copper pillar produce by filling through hole.

FIG. 2 shows a cross section of the high surface are capacitor with electroplated copper nano particles and the materials key where the dielectric material is HfO₂, BaTiO₃ or other dielectric layer.

FIG. 3 shows electroplated nano particles forms on a copper pillar.

FIG. 4 shows a through hole via with 65 μm diameter, 72 μm center-to-center pitch.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims.

Photodefinable glass materials are processed using first generation semiconductor equipment in a simple three step process where the final material can be fashioned into either glass, ceramic, or contain regions of both glass and ceramic. Photodefinable glass has several advantages for the fabrication of a wide variety of microsystems components, systems on a chip and systems in a package. Microstructures and electronic components have been produced relatively inexpensively with these types of glass using conventional semiconductor and printed circuit board (PCB) processing equipment. In general, glass has high temperature stability, good mechanical and electrically properties, and a better chemical resistance than plastics as well as many types of metals.

When exposed to UV-light within the absorption band of cerium oxide, the cerium oxide acts as a sensitizer by absorbing a photon and losing an electron. This reaction reduces neighboring silver oxide to form silver atoms, e.g.,

Ce³⁺+Ag⁺=□Ce⁴⁺+Ag⁰

The silver ions coalesce into silver nano-clusters during the heat treatment process and induce nucleation sites for the formation of a crystalline ceramic phase in the surrounding glass. This heat treatment must be performed at a temperature near the glass transformation temperature. The ceramic crystalline phase is more soluble in etchants, such as hydrofluoric acid (HF), than the unexposed vitreous, amorphous glassy regions. In particular, the crystalline [ceramic] regions of FOTURAN® are etched about 20 times faster than the amorphous regions in 10% HF, enabling microstructures with wall slope ratios of about 20:1 when the exposed regions are removed. See T. R. Dietrich et al., “Fabrication technologies for microsystems utilizing photoetchable glass,” Microelectronic Engineering 30, 497 (1996), which is incorporated herein by reference. Other compositions of photodefinable glass will etch at different rates.

One method of fabricating a metal device using a photosensitive glass substrate—comprised of silica, lithium oxide, aluminum oxide and cerium oxide—involves the use of a mask and UV light to create a pattern with at least one, 2-dimensional or 3-dimensional, ceramic phase region within the photosensitive glass substrate.

Preferably, the shaped glass structure contains at least one or more, two or three dimensional inductive device. The capacitive device is formed by making a series of connected structures to form a high surface area capacitor for power condition. The structures can be either rectangular, circular, elliptical, fractal or other shapes that create a pattern that generates capacitance. The patterned regions of the APEX™ glass can be filled with metal, alloys, composites, glass or other magnetic media, by a number of methods including plating or vapor phase deposition. The electrical permittivity of the media combined with the dimensions, high surface area and number of structures in the device provide the inductance of devices. Depending on the frequency of operation the inductive device design will require different magnetic permittivity materials, so at higher frequency operations material such as copper or other similar material is the media of choice for inductive devices. Once the capacitive device has been generated the supporting APEX™ glass can be left in place or removed to create an array of capacitive structures that can be attached in series or in parallel.

This process can be used to create a large surface area capacitor that will exceed the desired technical requirements for an high surface area capacitor conditioning capacitance density with values of greater than or equal to 1 nf up to 100 μf There are different device architectures based on the relative permittivity used and the preferred deposition technique for the dielectric material. This invention provides a method to create a device architectures for each dielectric material.

Generally, glass ceramics materials have had limited success in microstructure formation plagued by performance, uniformity, usability by others and availability issues. Past glass-ceramic materials have yielded an etch aspect-ratio of approximately 15:1, in contrast APEX® glass has an average etch aspect ratio greater than 26:1 to 50:1. This allows users to create smaller and deeper features. Additionally, our manufacturing process enables product yields of greater than 90% (legacy glass yields are closer to 50%). Lastly, in legacy glass ceramics, approximately only 30% of the glass is converted into the ceramic state, whereas with APEX® glass ceramic this conversion is closer to 70%.

The APEX® composition provides three main mechanisms for its enhanced performance: (1) the higher amount of silver leads to the formation of smaller ceramic crystals which are etched faster at the grain boundaries, (2) the decrease in silica content (the main constituent etched by the HF acid) decreases the undesired etching of unexposed material, and (3) the higher total weight percent of the alkali metals and boron oxide produces a much more homogeneous glass during manufacturing.

Ceramicization of the glass is accomplished by exposing the entire glass substrate to approximately 20 J/cm² of 310 nm light. When trying to create glass spaces within the ceramic, users expose all of the material, except where the glass is to remain glass. In one embodiment, the present invention provides a quartz/chrome mask containing a variety of concentric circles with different diameters.

The invention uses metal pillar created by either an additive or subtractive process. An example of an additive process is electroplating, CVD or other such process. An example of an subtractive process is plasma or reactive ion beam etching or other such process. Both technical processes (Additive and/or Subtractive) produce a copper pillar on a copper/metal substrate. The solid metal/copper pillar and substrate minimizes the series resistance in all capacitive devices. The series resistance s Practical capacitors and inductors as used in electric circuits are not ideal components with only capacitance or inductance. Ideal capacitors and inductors have a series with a resistance; this resistance is defined as the equivalent series resistance (ESR). The ESR effects the self-resonant frequency for capacitors and inductors “Q factor”. The lower the ESR the higher the Q factor. Using this innovation 3DGS has shown a Q greater than 400 in both inductors and capacitors.

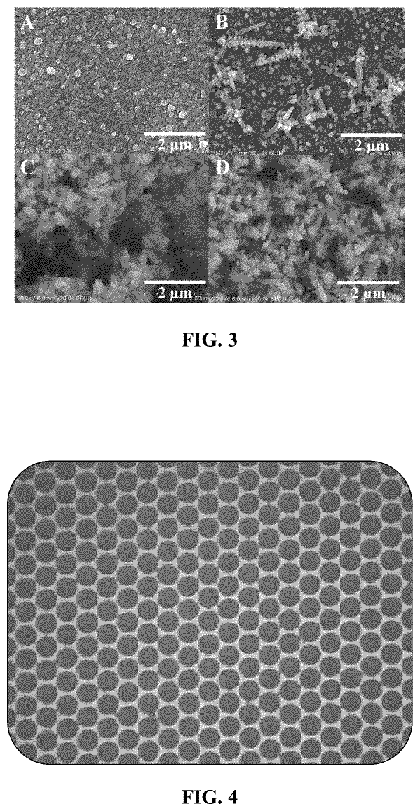

To achieve substantially greater surface areas of a capacitor uses the innovation electroplating a nano particle forms on the surface of the copper pillar. This can be seen in FIG. 2 and FIG. 3. The electroplated nano forms create a significant increase to the surface area of the metal pillar, e.g., by at least one of: increasing the surface roughness, adding nanoforms, adding different nanoforms, adding multiple layers, and combinations thereof.

The metalized pillar is then coated with a thin film of dielectric material such as a 20 nm layer of Al₂O₃ using an ALD process then applying a top metallization to make a large capacitance due to the effect surface area of the via(s) and the conformal ultra-thin coating of the dielectric uniformly coats the nano forms on the metal pillars.

The present invention includes a method for fabricating an inductive device in or on glass ceramic structure electrical microwave and radio frequency applications. The glass ceramic substrate may be a photosensitive glass substrate having a wide number of compositional variations including but not limited to: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B2O3, and 6-7 weight % Al₂O₃; with the combination of B₂O₃; and Al₂O₃ not exceeding 13 weight %; 8-15 weight % Li₂O; and 0.001-0.1 weight % CeO₂. This and other varied compositions are generally referred to as the APEX® glass.

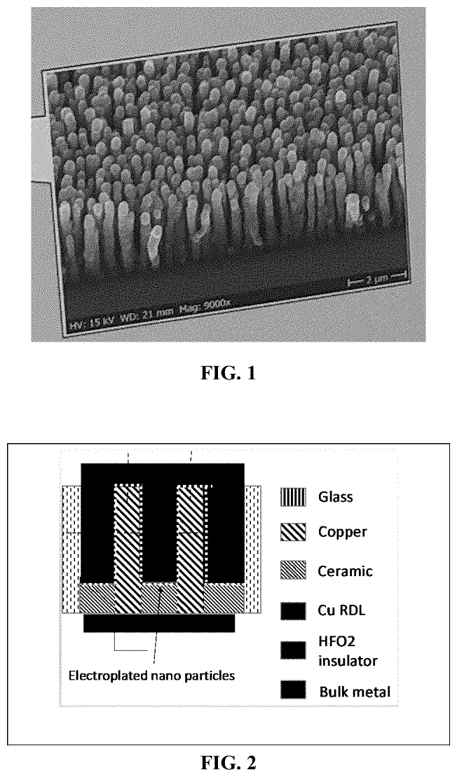

The exposed portion of the glass may be transformed into a crystalline material by heating the glass substrate to a temperature near the glass transformation temperature. When etching the glass substrate in an etchant such as hydrofluoric acid, the anisotropic-etch ratio of the exposed portion to the unexposed portion is at least 30:1 when the glass is exposed to a broad spectrum mid-ultraviolet (about 308-312 nm) flood lamp to provide a shaped glass structure that has an aspect ratio of at least 26:1, 27:1, 28:1, 29:1, 30:1, or greater, and to create an inductive structure. The mask for the exposure can be of a halftone mask that provides a continuous grey scale to the exposure to form a curved structure for the creation of an inductive structure/device. A digital mask can also be used with the flood exposure and can be used to produce the creation of an inductive structure/device. The exposed glass is then baked, typically in a two-step process. Temperature range heated between 420° C.-520° C. for between 10 minutes to 2 hours, for the coalescing of silver ions into silver nanoparticles and temperature range heated between 520° C.-620° C. for between 10 minutes and 2 hours allowing the lithium oxide to form around the silver nanoparticles. The glass plate is then etched. The glass substrate is etched in an etchant, of HF solution, typically 5% to 10% by volume, wherein the etch ratio of exposed portion to that of the unexposed portion is at least 30:1 when exposed with a broad spectrum mid-ultraviolet flood light, and greater than 30:1 when exposed with a laser, to provide a shaped glass structure with an anisotropic-etch ratio of at least 30:1. FIG. 1 shows the image of copper electroplated filled through hole via with seed layer.

The present invention includes capacitive structures created in the multiple metal posts in a glass-ceramic substrate, such process employing the photodefinable glass structure in a wafer containing at least one or more, two or three-dimensional capacitor device. The photodefinable glass wafer can range from 50 μm to 1,000 μm, preferably 100, 150, 200, 250, 300, 350,400, 500, 600, 700, 800, or 900 μm. The photodefinable glass is then patterned with a circular pattern and etched through the volume of the glass. The circular pattern can range from 5 μm to 250 μm in diameter but is preferably 30 μm in diameter. A uniform seed layer is deposited across the wafer including the vias by a CVD process. The seed layer thickness can range from 50 nm to 1000 nm but is preferably 150 nm in thickness. The wafer is then placed into an electroplating bath where copper (Cu) is deposited on the seed layer. The copper layer needs to be sufficient to fill the via, in this case 25 μm. The front side and backside of the wafer is the lapped and polished back to the photodefinable glass. A rectangular pattern is made in the photodefinable glass using the process described earlier to convert between 10% and 90% of the glass, preferably 80% of the volume of the photodefinable glass. The via may also receive an additional low concentrated rinse, with an etchant, such as dilute HF. The dilute HF will pattern or texture the ceramic wall of the via. The texturing of the ceramic wall significantly increases the surface area of the structure, directly increasing the capacitance of the device. The photodefinable glass with the exposed copper has a metalized polyimide is placed in physical/electrical contact to the copper filled via on the backside of the wafer. The metalized polyimide contacted photodefinable glass with the exposed copper columns are placed into a electroplating bath where a flash coating of non-oxidizing metal or a metal that forms a semiconductor oxide or conductive oxide is electroplated on the surface of the metal posts. This metal is preferably gold (Au). The thin flash coating prevents the oxidation of the copper posts during the deposition of the dielectric media/material. The surface of the metal pillar is then coated with nano forms using an electroplating technique creating a significant increase to the surface area relative to the pillar by itself. The surface area is increase by the size and shape of the nanoform. A nanoform of a 20 nm spherical will increase the surface area by over 200 times. A electroplated nanoform of a 200 nm spherical will increase the surface area by over 10 times. The two different nanoforms can be electroplated sequentially with the largest nanoform first then moving to smaller nanoforms will create a compound nanoform structure electroplated on the pillar. The compound nanoform capacitor structure can achieve a capacitance value greater than 10 with low ESR. The nanoforms may also be a carbon nanotube, carbon nanoplate, carbon nanoforest, a carbon nanosphere, a metal, a semiconductor, or metal nanobeads.

A dielectric layer is then deposited using an atomic layer deposition (ALD) process to deposit a metal that can be oxidized or directly deposit a oxide material such as 10A of the dielectric layer of Ta₂O₅, Al₂O₃ or other vapor phase dielectrics including but not limited to Al₂O₃. Al₂O₃ at 380° C. using TMA and O₃—cycle time: 3.5 s. The Al₂O₃ layer is then heated in oxygen ambient to 300° C. for 5 min fully oxidized the dielectric layer. The thickness of this dielectric layer can range from 5 nm to 1000 nm. Our preferred thickness is 5 nm thick. Next a RLD of copper is deposited to fill the rectangular hole. The RLD is preferably a copper paste that is deposited by a silk screening process. The wafer is then placed into a furnace that is heated to between 450° C. to 700° C. for between 5 and 60 min in an inert gas or vacuum environment. Our preferred temperature and time is 600° C. for 20 min in argon gas. The last step is to make contact to the RLD copper making the front surface of the die into rows and backside of the wafer into columns. All of the rows on the front surface are tied together in parallel to make an electrode for a large integrated surface area capacitor. Similarly, all of the columns on the back surface of the die are tied together in parallel to make a bottom electrode for a large integrated surface area capacitor.

A second embodiment can be seen in FIG. 3. The present invention includes capacitive structures created in the multiple metal posts or an array in a glass-ceramic substrate, such process employing the photodefinable glass structure in a wafer containing at least one or more, two or three-dimensional capacitor device. FIG. 3 shows the electroplated metallic nanoparticles that increase surface area of the capacitor. The photodefinable glass wafer can range from 50 μm to 1,000 μm, in our case preferably 500 μm. The photodefinable glass is then patterned with a circular pattern and etched through the volume of the glass. The circular or pillar pattern can range from 5 μm to 250 μm in diameter but preferably 30 μm in diameter. A uniform titanium seed layer is deposited across the wafer including the vias by a CVD process. The seed layer thickness can range from 50 nm to 1000 nm, but is preferably 150 nm in thickness. The wafer is then placed into an electroplating bath where copper (Cu) is deposited on the seed layer. The copper layer needs to be sufficient to fill the via, in this case 25 μm. The front side and backside of the wafer is the lapped and polished back to the photodefinable glass. This can be seen in FIG. 2. A pillar pattern is made in the photodefinable glass using the process described earlier to convert between 10% and 90% of the glass, preferably 80% of the volume of the photodefinable glass. The via may also receive an additional low concentrated rinse, with an etchant, such as dilute HF. The metalized polyimide contacted photodefinable glass with the exposed copper columns are placed into a electroplating bath where a flash coating of non-oxidizing metal or a metal that forms a semiconductor oxide or conductive oxide is electroplated on the surface of the metal posts. This metal is preferably gold (Au). The thin flash coating prevents the oxidation of the copper posts during the deposition of the dielectric media/material. A dielectric region is then created by use of commercially available BaTiO₃ paste that is silk-screened into the rectangular wells. The wafer is then placed into a furnace that is heated to between 450° C. to 700° C. for between 5 and 60 min in an oxygen ambient. A preferred temperature and time is 600° C. for 30 min in oxygen ambient. The last step is to make contact to the RLD copper making the front surface of the die into rows and backside of the wafer into rows that are parallel to the top electrodes. All of the rows on the front surface are tied together in parallel to make an electrode for a large integrated surface area capacitor. Similarly, all of the rows on the back surface of the die are tied together in parallel to make a bottom electrode for a large integrated surface area capacitor.

The surface area of the capacitor can also be increased by growing carbon nanotubes (CNT) onto the copper surfaces through a variety of techniques including aqueous paths and CVD paths, which are shown in FIG. 1. CNTs have been shown to hold 350 nF/mm². Combining 3DGS pillar technology with CNTs can increase capacitance density to @34 mm\hat{ }2 pillar area: 11.9 uF/mm² footprint, or @53 mm\hat{ }2 pillar area: 18.5 uF/mm² footprint.

FIG. 4 shows a through hole via with 65 μm diameter, 72 μm center-to-center pitch. Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

This invention creates a cost-effective glass ceramic electroplated nano form enabled ultra-high surface area three-dimensional capacitor structure or three-dimensional capacitor array device. Where a glass ceramic substrate has demonstrated capability to form such structures through the processing of both the vertical as well as horizontal planes either separately or at the same time to form two or three-dimensional capacitive devices.

The present invention includes a method to fabricate a substrate with one or more, two or three dimensional capacitor devices by preparing a photosensitive glass substrate with via or post and further coating or filling with one or more conductive layer typically a metal, dielectric material and a top layer conductive layer typically a metal.

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not restrict the scope of the invention.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

1. A method of making an integrated large capacitance in a small form factor for power conditioning in a photodefinable glass substrate comprising:
depositing a conductive seed layer on a photodefinable glass substrate processed to form one or more via openings in the photodefinable glass substrate;
placing the photodefinable glass substrate with a metallized seed layer electroplating metal to fill one or more openings in the photodefinable glass substrate to form vias;
chemically-mechanically polishing a front and a back surface of the photodefinable glass substrate to leave only the filled vias;
exposing and converting at least one generally rectangular portion of the photosensitive glass substrate around two adjacent filled vias;
etching the rectangular portion exposing at least one pair of adjacent filled vias to form metal posts;
flash coating a non-oxidizing layer on the metal posts that form a first electrode;
coating, at least once, at least a portion of the metal posts, the non-oxidizing layer, or both, with one or more nanoforms by electroplating to increase a surface area of the metal posts;
depositing a dielectric layer on or around the posts;
metal coating the dielectric layer to form a second electrode;
connecting a first metal layer to all of the first electrodes in parallel to form a single electrode for a capacitor; and
connecting a second metal layer to all of the second electrodes in parallel to form a second electrode for the capacitor.

2. The method of claim 1, wherein the nanoform is a carbon nanotube, carbon nanoplate, carbon nanoforest, a carbon nanosphere, a metal, a semiconductor, or metal nanobeads.

3. The method of claim 1, wherein the nanoform is generally spherical and has a diameter of 20 nm to 200 nm.

4. The method of claim 1, wherein two or more different nanoforms are coated onto the metal posts.

5. The method of claim 1, wherein the dielectric layer is a thin film between 0.5 nm and 1000 nm thick.

6. The method of claim 1, wherein the dielectric layer is a sintered paste between 0.05 μm and 100 μm thick.

7. The method of claim 1, wherein the dielectric layer has an electrical permittivity between 10 and 10,000.

8. The method of claim 1, wherein the dielectric layer has an electrical permittivity between 2 and 100.

9. The method of claim 1, wherein the dielectric layer is deposited by atomic layer deposition.

10. The method of claim 1, wherein the capacitor has a capacitance density greater than 1 of/mm².

11. The method of claim 1, wherein the capacitor has a capacitance of 1 nf to 100 μf.

12. A method of making an integrated large capacitance in a small form factor for power conditioning on a photodefinable glass substrate comprising:
masking a circular pattern on the photosensitive glass substrate;
exposing at least one portion of the photosensitive glass substrate to an activating UV energy source;
heating the photosensitive glass substrate to a heating phase of at least ten minutes above its glass transition temperature;
cooling the photosensitive glass substrate to transform at least part of the exposed glass to a crystalline material to form a glass—ceramic crystalline substrate;
partially etching away the ceramic phase of the photodefinable glass substrate with an etchant solution;
depositing a conductive seed layer on the photodefinable glass substrate;
placing the photodefinable glass substrate with a metallized seed layer electroplating metal to fill one or more openings in the photodefinable glass substrate to form vias;
chemically-mechanically polishing a front and a back surface of the photodefinable glass substrate to leave only the filled vias;
exposing and converting at least one rectangular portion of the photosensitive glass substrate around two adjacent filled vias;
etching the rectangular patent portion exposing at least one pair of adjacent filled vias to form metal posts;
flash coating a non-oxidizing layer on the metal posts that form a first electrode;
coating, at least once, at least a portion of the metal posts, the non-oxidizing layer, or both, with one or more nanoforms by electroplating to increase a surface area of the metal posts;
depositing a dielectric layer on or around the posts;
metal coating the dielectric layer to form a second electrode;
connecting a first metal layer to all of the first electrodes in parallel to form a single electrode for a capacitor; and
connecting a second metal layer to all of the second electrodes in parallel to form a second electrode for a capacitor.

13. The method of claim 12, wherein the nanoform is a carbon nanotube, carbon nanoplate, carbon nanoforest, a carbon nanosphere, a metal, a semiconductor, or metal nanobeads.

14. The method of claim 12, wherein the nanoform is generally spherical and has a diameter of 20 nm to 200 nm.

15. The method of claim 12, wherein two or more different nanoforms are coated onto the metal posts.

16. The method of claim 12, wherein the dielectric layer is a thin film between 0.5 nm and 1000 nm thick.

17. The method of claim 12, wherein the dielectric layer is a sintered paste between 0.05 μm and 100 μm thick.

18. The method of claim 12, wherein the dielectric layer has an electrical permittivity between 10 and 10,000.

19. The method of claim 12, wherein the dielectric layer has an electrical permittivity between 2 and 100.

20. The method of claim 12, wherein the dielectric layer is deposited by atomic layer deposition.

21. The method of claim 12, wherein the capacitor has a capacitance density greater than 1 of/mm².

22. The method of claim 12, wherein the capacitor has a capacitance of 1 nf to 100 μf.

23. An integrated capacitor made by a method comprising:
masking a circular pattern on a photosensitive glass substrate;
exposing at least one portion of the photosensitive glass substrate to an activating UV energy source;
heating the photosensitive glass substrate to a heating phase of at least ten minutes above its glass transition temperature;
cooling the photosensitive glass substrate to transform at least part of the exposed glass to a crystalline material to form a glass—ceramic crystalline substrate;
partially etching away the ceramic phase of the photodefinable glass substrate with an etchant solution;
depositing a conductive seed layer on the photodefinable glass substrate;
placing the photodefinable glass substrate with a metallized seed layer electroplating metal to fill one or more openings in the photodefinable glass substrate to form vias;
chemically-mechanically polishing a front and a back surface of the photodefinable glass substrate to leave only the filled vias;
exposing and converting at least one rectangular portion of the photosensitive glass substrate around two adjacent filled vias;
etching the rectangular portion exposing at least one pair of adjacent filled vias to form metal posts;
flash coating a non-oxidizing layer on the metal posts that form a first electrode;
coating, at least once, at least a portion of the metal posts, the non-oxidizing layer, or both, with one or more nanoforms by electroplating to increase a surface area of the metal posts;
depositing a dielectric layer on or around the posts;
metal coating the dielectric layer to form a second electrode;
connecting a first metal layer to all of the first electrodes in parallel to form a single electrode for a capacitor; and
connecting a second metal layer to all of the second electrodes in parallel to form a second electrode for the capacitor.

24. The capacitor of claim 23, wherein the nanoform is a carbon nanotube, carbon nanoplate, carbon nanoforest, a carbon nanosphere, a metal, a semiconductor, or metal nanobeads.

25. The capacitor of claim 23, wherein the nanoform is generally spherical and has a diameter of 20 nm to 200 nm.

26. The capacitor of claim 23, wherein two or more different nanoforms are coated onto the metal posts.

27. The capacitor of claim 23, wherein the dielectric layer is a thin film between 0.5 nm and 1000 nm thick.

28. The capacitor of claim 23, wherein the dielectric layer is a sintered paste between 0.05 μm and 100 μm thick.

29. The capacitor of claim 23, wherein the dielectric material has an electrical permittivity between 10 and 10,000.

30. The capacitor of claim 23, wherein the dielectric thin film has an electrical permittivity between 2 and 100.

31. The capacitor of claim 23, wherein the dielectric thin film material is deposited by atomic layer deposition.

32. The capacitor of claim 23, wherein the capacitor has a capacitance density greater than 1 nf/mm².

33. The capacitor of claim 23, wherein the capacitor has a capacitance of 1 nf to 100 μf.

34. A capacitor comprising:
a plurality of metal pillars onto which a plurality of nanoforms are electroplated to increase the surface area of the metal pillars;
a dielectric layer on the metal pillars and nanoforms; and
a conductive layer on the dielectric layer opposite the metal pillars and nanoforms.

35. The capacitor of claim 34, wherein the capacitor has a capacitance density greater than 1 nf/mm².

36. The capacitor of claim 34, wherein a non-oxidizing metal layer is disposed between the metal pillars and the nanoforms.

37. The capacitor of claim 34, wherein the nanoform is a carbon nanotube, carbon nanoplate, carbon nanoforest, a carbon nanosphere, a metal, a semiconductor, or metal nanobeads.

38. The capacitor of claim 34, wherein the nanoform is generally spherical and has a diameter of 20 nm to 200 nm.
